(19) United States
(12) Patent Application Publication
(10) Pub. No.: US 2013/0094152 A1
(43) Pub. Date: Apr. 18, 2013

(54) ELECTRONIC DEVICE AND HEAT SINK EMPLOYING THE SAME

(71) Applicants: HUI LI, Shenzhen City (CN); YA-JUN PAN, Shenzhen City (CN); TING GE, Shenzhen City (CN)

(72) Inventors: HUI LI, Shenzhen City (CN); YA-JUN PAN, Shenzhen City (CN); TING GE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/455,818

(22) Filed: Apr. 25, 2012

(30) Foreign Application Priority Data
Oct. 13, 2011 (CN) 201120388832.7

(51) Int. Cl. H05K 7/20

(52) U.S. Cl. 361/720

(57) ABSTRACT

A heat sink is used to cool electronic components, and includes a metal base portion, a motherboard and a heat conducting sheet. The motherboard and the heat conducting sheet are positioned on the metal base portion. The motherboard includes a copper foil. The electronic components are electrically connected on the copper foil; the heat conducting sheet is positioned between the metal base portion and the motherboard, and contacts the metal base portion and the motherboard. The heat of the electronic components is conducted to the metal base portion through the copper foil, the motherboard and the heat conducting sheet.

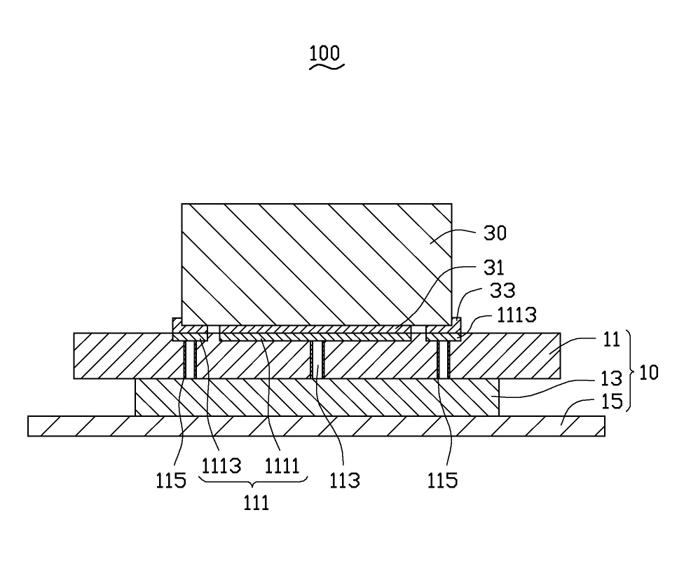

### BACKGROUND

1. Technical field

The disclosure generally relates to a heat sink used to cool an electronic device.

2. Description of the Related Art

Electronic components, for example, high-power semiconductor devices and optoelectronic devices, can generate a great amount of heat while working in electronic devices (e.g., computers and servers). Thus, one or more heat radiating fins are usually used to cool the electronic components by dissipating heat into the surrounding air. However, the heat radiating fin(s) are usually large, and occupy a larger inner space in the electronic device and therefore cannot meet the needs of miniaturization of the decreasing electronic devices.

Therefore, there is room for improvement within the art.

### BRIEF DESCRIPTION OF THE DRAWINGS

Many aspects of an electronic device and heat sink employing the same can be better understood with reference to the drawing. The components in the drawing are not necessarily drawn to scale, the emphasis instead being placed upon clearly illustrating the principles of the radio frequency circuit.

The drawing is an assembled cross-sectional view of an exemplary embodiment of an electronic device of the disclosure.

### DETAILED DESCRIPTION

The drawing is an assembled cross-sectional view of an exemplary embodiment of an electronic device 100 of the disclosure. The electronic device 100 can be a computer or server, and includes a heat sink 10 and a plurality of electronic components 30 therein. The heat sink 10 is used to cool the electronic components 30 in the electronic device 100 by dissipating heat into the surrounding air. In the exemplary embodiment, the electronic components 30 can be high-power semiconductor devices and optoelectronic device such as higher-power lasers and light emitting diodes.

The heat sink 10 includes a motherboard 11, a heat conducting sheet 13, and a metal base portion 15. In the exemplary embodiment, the motherboard 11 and the heat conducting sheet 13 are positioned on the metal base portion 15, the heat conducting sheet 13 is located between the motherboard 11 and the base portion 15, and contacts the motherboard 11 and the base portion 15. The electronic components 30 are electrically positioned on the motherboard 11 by, for example, soldering or welding, so that the heat from the electronic components 30 are conducted to the base portion 15 through the motherboard 11 and the heat conducting sheet 13, and then dissipated into the surrounding air from the electronic device 100.

The motherboard 11 includes a copper foil 111 corresponding in size and shape to the electronic components 30. The copper foil 111 is located on the surface of the motherboard 11, and includes a plurality of signal lines (not shown) and a plurality of bonding pad regions (described in detail, below) electrically connected to the signal lines. A number of bonding pads are formed on the corresponding bonding pad regions. The electronic components 30 are positioned on the corresponding bonding pads by, for example, soldering or welding, and are electrically connected to the motherboard 11 through the bonding pads. Thus, heat from the electronic components 30 can be conducted to the motherboard 11 through the bonding pads.

In the exemplary embodiment, each bonding pad region includes a first bonding region portion 1111 and a plurality of second bonding region portions 1113. Each first bonding region portion 1111 is surrounded by a plurality of (e.g., four) second bonding region portions 1113. The combination of each first bonding region portion 1111 and its surrounding second bonding region portions 1113 forms a bonding pad group. A first bonding pad 31 is formed on each corresponding first bonding region portion 1111, and a second bonding pad 33 is formed on each second bonding region portion 1113. When an electronic component 30 is located on a first bonding pad 31 and a plurality of surrounding second bonding pads 33, where the first bonding pad 31 is electrically connected to an electronic component 30 and ground, the connections between the bonding pads 31 and 33 and the bonding region portions 1111 and 1113 conduct the heat from the contacted electronic component 30 to the upper surface of the motherboard 11. In the exemplary embodiment, the size of the first bonding pad 31 is greater than the size of each of the surrounding second bonding pads 33.

The motherboard 11 defines a plurality of through holes 113 arranged on the surface of the motherboard 11. Each through hole 113 extends through the motherboard 11 and is optionally coated with a metal layer 115, such as copper, on the inner surface, and is formed between the copper foil 111 and the heat conducting sheet 13. The coated metal layers 115 contact the first bonding region portions 1111 and the second bonding region portions 1113 of the copper foil 111, and contact the heat conducting sheet 13. Thus, the heat from the electronic components 30 can be conducted to the base portion 15 through the bonding pads, the copper foil 111, the metal layers 115 and the heat conducting sheet 13 in turn, and is further dissipated into the surrounding air from the electronic device 100.

In the exemplary embodiment, the thickness of the heat conducting sheet 13 is about 0.5 mm-5 mm, the density of the heat conducting sheet 13 is about 2.8 g/cm³, the end-use temperature (i.e., operating temperature or service temperature) is about −60° C. ˜200° C., and the heat transfer coefficient is about 2.8 W/(m²K), which is used in calculating the heat transfer, by convection or phase change between a fluid and a solid.

In summary, in the heat sink 10 of this disclosure, the copper foil 111 is located on the motherboard 11 and contacts the electronic components 30 to absorb the heat from the electronic components 30. The heat conducting sheet 13 is positioned between the motherboard 11 and the base portion 15 of the electronic device 100, so that the heat absorbed by the copper foil 111 is conducted to the base portion 15 through the heat conducting sheet 13, and is further dissipated into the surrounding air to cool the electronic components 30. Moreover, the heat conducting sheet 13 has a small size and can be assembled within the reserved space between the motherboard 11 and the base portion 13, thus avoiding add the heat radiating fins and saving the inner space of the electronic device 100.

In the present specification and claims, the word “a” or “an” preceding an element does not exclude the presence of a plurality of such elements. Further, the word “comprising” does not exclude the presence of elements or steps other than those listed.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in the matters of shape, size, and arrangement of parts within the principles of this exemplary disclosure to the full extent indicated by the broad general meaning of the terms in which the appended claims are expressed.

What is claimed is:

1. A heat sink used for cooling electronic components, the heat sink comprising:
a metal base portion;
a motherboard positioned on the metal base portion, and the motherboard comprising a copper foil and a plurality of metal layers extending through the motherboard; and
a heat conducting sheet positioned on the metal base portion, wherein the electronic components are electrically connected on the copper foil, the heat conducting sheet is positioned between the metal base portion and the motherboard, and contacts the metal base portion and the motherboard, and heat from the electronic components is conducted to the metal base portion through the copper foil, the metal layers of the motherboard and the heat conducting sheet.

2. The heat sink as claimed in claim 1, wherein the copper foil comprises a plurality of first bonding region portions and a plurality of second bonding region portions, and each first bonding region portion is surrounded by a plurality of second bonding region portions, and the combination of each first bonding region portion and its surrounding second bonding region portions forms a bonding pad group.

3. The heat sink as claimed in claim 2, wherein the copper foil further comprises a plurality of first bonding pads and a plurality of second bonding pads, a first bonding pads is are formed on each corresponding first bonding region portion, and a second bonding pad is formed on each second bonding region portion.

4. The heat sink as claimed in claim 3, wherein the size of the first bonding pad is greater than that of each of the surrounding second bonding pads.

5. The heat sink as claimed in claim 3, wherein the motherboard defines a plurality of through holes arranged on the surface of the motherboard, and each through hole extends through the motherboard and is coated with the metal layer of metal on the inner surface.

6. The heat sink as claimed in claim 5, wherein the through holes with coated metal layers are formed between the copper foil and the heat conducting sheet, and the coated metal layers contact the first bonding region portions and the second bonding region portions of the copper foil, and contact the heat conducting sheet, and the heat from the electronic components is conducted to the metal base portion through the bonding pads, the copper foil, the metal layers and the heat conducting sheet and is dissipated into the surrounding air from the electronic device.

7. The heat sink as claimed in claim 1, wherein the thickness of the heat conducting sheet is 0.5 mm-5 mm, the density of the heat conducting sheet is 2.8 g/cm³.

8. The heat sink as claimed in claim 1, wherein the end-use temperature of the heat conducting sheet is −60° C.˜200° C.

9. The heat sink as claimed in claim 1, wherein the heat transfer coefficient of the heat conducting sheet is about 2.8 W/(m²K), where the heat transfer coefficient is used in calculating the heat transfer, by convection or phase change between a fluid and a solid.

10. An electronic device comprising:
a plurality of electronic components; and
a heat sink cooling the electronic components, and the heat sink comprising:
a metal base portion;
a heat conducting sheet position on the metal base portion, and the metal base portion contacting one surface of the heat conducting sheet; and
a motherboard positioned on the metal base portion, wherein the motherboard contacts the opposite surface of the heat conducting sheet, the motherboard comprises a plurality of copper layers extending through the motherboard and a copper foil on the surface of the motherboard opposite to the heat conducting sheet, and heat of the electronic components is conducted from the copper foil, the copper layers of the motherboard and the heat conducting sheet to the metal base portion, and is dissipated out of the electronic device.

11. The heat sink as claimed in claim 10, wherein the copper foil comprises a plurality of first bonding region portions and a plurality of second bonding region portions, and each first bonding region portion is surrounded by a plurality of second bonding region portions, and the combination of each first bonding region portion and its surrounding second bonding region portions forms a bonding pad group.

12. The heat sink as claimed in claim 11, wherein the copper foil further comprises a plurality of first bonding pads and a plurality of second bonding pads, a first bonding pads is formed on each corresponding first bonding region portion, and a second bonding pad is formed on each second bonding region portion.

13. The heat sink as claimed in claim 12, wherein the size of the first bonding pad is greater than that of each of the surrounding second bonding pads.

14. The heat sink as claimed in claim 12, wherein the motherboard defines a plurality of through holes arranged on the surface of the motherboard, and each through hole extends through the motherboard and is coated with the copper layer on the inner surface.

15. The heat sink as claimed in claim 14, wherein the through holes with coated copper layers are formed between the copper foil and the heat conducting sheet, and the coated copper layers contact the first bonding region portions and the second bonding region portions of the copper foil, and contact the heat conducting sheet, and the heat from the electronic components is conducted to the metal base portion through the bonding pads, the copper foil, the copper layers and the heat conducting sheet and is dissipated into the surrounding air from the electronic device.

16. The heat sink as claimed in claim 10, wherein the thickness of the heat conducting sheet is 0.5 mm-5 mm, the density of the heat conducting sheet is 2.8 g/cm³.

17. The heat sink as claimed in claim 10, wherein the end-use temperature of the heat conducting sheet is −60° C.˜200° C.

18. The heat sink as claimed in claim 10, wherein the heat transfer coefficient of the heat conducting sheet is about 2.8 W/(m²K), where the heat transfer coefficient is used in calculating the heat transfer, by convection or phase change between a fluid and a solid.
